(19) United States
(12) Patent Application Publication
(10) Pub. No.: US 2021/0328181 A1
(43) Pub. Date: Oct. 21, 2021

(54) ORGANIC LIGHT-EMITTING DIODE DISPLAY PANEL AND MANUFACTURING METHOD THEREOF, AND ENCAPSULATION THIN-FILM

(71) Applicant: WUHAN CHINA STAR OPTOELECTRONICS SEMICONDUCTOR DISPLAY TECHNOLOGY CO., LTD., WUHAN (CN)

(72) Inventor: GAOZHEN WANG, WUHAN (CN)

(21) Appl. No.: 16/619,187

(22) PCT Filed: Aug. 8, 2019
(86) PCT No.: PCT/CN2019/099713

§ 371 Date: Dec. 4, 2019

(30) Foreign Application Priority Data
Jun. 14, 2019 (CN) 201910514676.5

(51) Int. Cl. H01L 51/52; H01L 51/56

(52) U.S. Cl. CPC H01L 51/5253; H01L 27/3246; H01L 51/56

(57) ABSTRACT

An organic light-emitting diode display panel and a manufacturing method thereof, and an encapsulation thin-film are provided. The ability of an encapsulation thin-film blocking water and oxygen from entering organic light-emitting devices can be ensured through adding an auxiliary encapsulation layer on at least one side of an inorganic layer, and through the auxiliary encapsulation layer covering an orthogonal projection of a photo spacer on a pixel define layer. Even if the inorganic layer breaks while covering the photo spacer, a channel for water and oxygen located at the breakage is blocked by the auxiliary encapsulation layer.

### BACKGROUND OF DISCLOSURE

### 1. Field of the Disclosure

The present disclosure relates to the field of organic light-emitting diode (OLED) display, and more particularly, to an organic light-emitting diode display panel and a manufacturing method thereof, and an encapsulation thin-film.

### 2. Description of the Related Art

Organic light-emitting diode (OLED) display panels have advantages of low costs, wide viewing angle, high contrast, and bendability. Currently, organic light-emitting diode display panels have acquired significant effects in the applications of small and large scales and continue to invade a market share of liquid crystal display (LCD).

Organic light-emitting devices are used as key components in organic light-emitting diode display panels. Water and oxygen have greater impacts on lives of the organic light-emitting devices. Firstly, water and oxygen are prone to react with conductive materials of cathodes of the organic light-emitting devices; secondly, water and oxygen are prone to react with a hole transport layer and an electronic transport layer of the organic light-emitting devices, further causing the organic light-emitting devices to fail. In order to solve the problem, the organic light-emitting devices are encapsulated using a thin film encapsulation (TFE) method in conventional organic light-emitting diode display panels. An encapsulation thin-film used in the TFE method includes inorganic layers and organic layers which overlap with each other to prevent water and oxygen from invading the organic light-emitting devices.

However, for an encapsulation thin-film used in the conventional TFE method, the capability of blocking water and oxygen is still not enough. Especially in a case of encapsulating a protrusive structure, a peeling is prone to occur in a region that the encapsulation thin-film covers the protrusive structure. The most common example is that the inorganic layers break, and thus a channel for water and oxygen is formed. Specifically, water and oxygen molecules invade holes of the inorganic layers through the channel for water and oxygen, and quickly pass through the organic layers due to the organic layers incapable of blocking water and oxygen. Then, water and oxygen molecules continuously move on the border between the inorganic layers and the organic layers, and continuously invade inward into the next hole of the inorganic layers until invading the organic light-emitting devices. From this, it can be seen that the breakage of the inorganic layers may significantly affect the capability of the encapsulation thin-film blocking water and oxygen molecules.

### SUMMARY

A technical problem is that an insufficient ability of an encapsulation thin-film blocking water and oxygen from entering organic light-emitting devices due to breakage of conventional inorganic layers.

The present disclosure provides an organic light-emitting diode display panel. The organic light-emitting diode display panel includes a pixel define layer, a photo spacer, and a first inorganic layer configured to encapsulate organic light-emitting devices. The photo spacer is located on the pixel define layer. The first inorganic layer covers the photo spacer and the pixel define layer, and a top surface of the first inorganic layer located on the pixel define layer is not flush with the rest of the top surface of the first inorganic layer in other regions. The organic light-emitting diode display panel further includes an auxiliary encapsulation layer located on at least one side of the first inorganic layer and covering an orthogonal projection of the photo spacer on the pixel define layer.

The present disclosure further provides an encapsulation thin-film. The encapsulation thin-film includes a main encapsulation layer and an auxiliary encapsulation layer. A top surface of the main encapsulation layer in a predetermined region is not flush with the rest of the top surface in other regions, and the auxiliary encapsulation layer is located on at least one side of the main encapsulation layer and covers the predetermined region.

The present disclosure further provides a method of manufacturing an organic light-emitting diode display panel. The method includes:

providing a substrate;

forming a pixel define layer on the substrate and forming a photo spacer on the pixel define layer;

forming organic light-emitting devices on the substrate and in a region defined by the pixel define layer;

forming a first inorganic layer and an auxiliary encapsulation layer, wherein the first inorganic layer covers the organic light-emitting devices, the photo spacer, and the pixel define layer, a top surface of the first inorganic layer located on the pixel define layer is not flush with the rest of the top surface of the first inorganic layer in other regions, and the auxiliary encapsulation layer is located on at least one side of the first inorganic layer and covers an orthogonal projection of the photo spacer on the pixel define layer;

forming an organic layer on the first inorganic layer; and

forming a second inorganic layer covering the organic layer.

The beneficial effect of the present disclosure is to ensure the ability of an encapsulation thin-film blocking water and oxygen from entering organic light-emitting devices through adding an auxiliary encapsulation layer on at least one side of an inorganic layer, and through the auxiliary encapsulation layer covering an orthogonal projection of a photo spacer on a pixel define layer. Even if the inorganic layer breaks while covering the photo spacer, a channel for water and oxygen located at the breakage is blocked by the auxiliary encapsulation layer.

### BRIEF DESCRIPTION OF DRAWINGS

FIG. 1 is a schematic structural diagram of an encapsulation thin-film according to a first embodiment of the present disclosure.

FIG. 2 is a schematic structural diagram of an encapsulation thin-film according to a second embodiment of the present disclosure.

FIG. 3 is a schematic structural diagram of an encapsulation thin-film according to a third embodiment of the present disclosure.

FIG. 4 is a schematic structural diagram of an organic light-emitting diode display panel according to a first embodiment of the present disclosure.

FIG. 5 is a schematic structural diagram of an organic light-emitting diode display panel according to a second embodiment of the present disclosure.

FIG. 6 is a schematic structural diagram of an organic light-emitting diode display panel according to a third embodiment of the present disclosure.

FIG. 7 is a schematic flowchart illustrating a method of manufacturing an organic light-emitting diode display panel according to an embodiment of the present disclosure.

### DETAILED DESCRIPTION OF EMBODIMENTS

The main object of the present disclosure is to ensure the ability of an encapsulation thin-film blocking water and oxygen from entering organic light-emitting devices through adding an auxiliary encapsulation layer on at least one side of an inorganic layer, and through the auxiliary encapsulation layer covering an orthogonal projection of a photo spacer on a pixel define layer. Even if the inorganic layer breaks while covering the photo spacer, a channel for water and oxygen located at the breakage is blocked by the auxiliary encapsulation layer.

For each exemplary embodiment provided in the present disclosure, their technical solutions will be clearly, completely described in conjunction with their accompanying drawings below. Without collisions, technical features can be assembled with each other in the following embodiments.

The directional terminologies of the invention, such as “up”, “down”, “top”, “bottom”, “front”, “back”, “left”, “right”, “inner”, “outer”, “side”, “around”, “central”, “level”, “lateral”, “perpendicular”, “longitudinal”, “axial”, “radial”, “uppermost”, “lowermost” and the like are merely the directions with reference to the accompanying drawings. Therefore, the aforesaid directional terminologies are used to describe and comprehend the invention without limiting the invention.

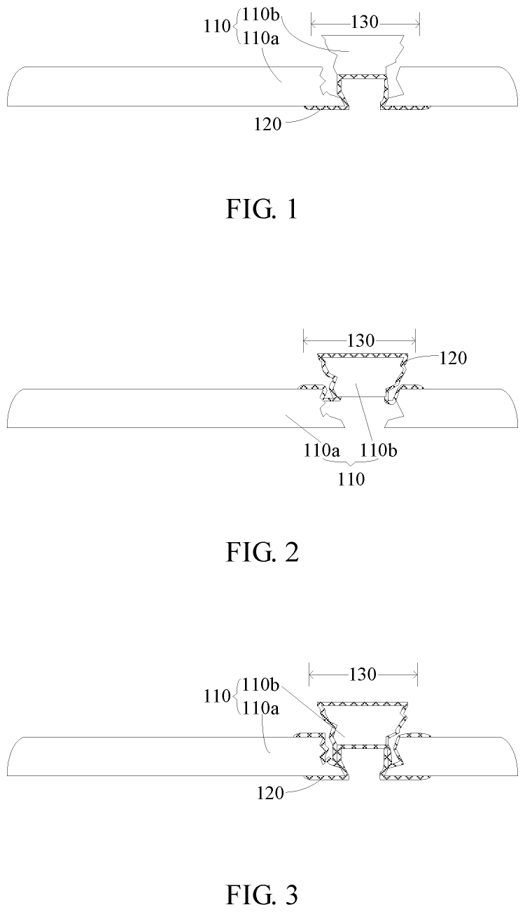

FIG. 1 is a schematic structural diagram of an encapsulation thin-film according to a first embodiment of the present disclosure. Referring to FIG. 1, an encapsulation thin-film 100 includes a main encapsulation layer 110 and an auxiliary encapsulation layer 120.

When the encapsulation thin-film 100 covers a protrusive structure, there is a height difference between a top surface of the main encapsulation layer 110 covering the protrusive structure and the rest of the top surface in other regions. That is, the top surface in two regions is not flush. In order to closely describe the improvements compared with conventional technologies, for example, that the main encapsulation layer 110 breaks due to the height difference will be described. Please refer to FIG. 1, a region where the protrusive structure is located is denoted by 130. When covering the protrusive structure, the main encapsulation layer 110 can break into two parts, that is, a main body 110a and a protrusion 110b. A top surface of the protrusion 110b is not flush with a top surface of the main body 110a.

The auxiliary encapsulation layer 120 covers a side of the main encapsulation layer 110, such as the underside of FIG. 1. Also, the auxiliary encapsulation layer 120 covers a region 130 where the protrusive structure is located. It can be selectable that the auxiliary encapsulation layer 120 can cover the whole of the region 130 where the protrusive structure is located, and also extend outward to overlap with a part of the underside of the main body 110a so that a larger coverage is realized.

In the encapsulation thin-film 100, the ability of the main encapsulation layer 110 blocking water and oxygen from entering the encapsulated devices can be ensured through adding the auxiliary encapsulation layer 120 on at least one side of the main encapsulation layer 110, and through the auxiliary encapsulation layer 120 covering the region 130 where the protrusive structure is located. Even if the main encapsulation layer 110 breaks while covering the region 130 where the protrusive structure is located, a channel for water and oxygen located at the breakage is blocked by the auxiliary encapsulation layer 120. It is beneficial to guarantee normal use of the encapsulated devices.

Thoroughly speaking, a material of the main encapsulation layer 110 can be an inorganic material, such as one or more of silicon nitride, silicone compound, silicone nitrogen oxide, aluminum oxide, and so on. It is allowed that the covered devices can have an uneven surface, such as a protrusive platform structure, due to the existence of the protrusion 110b when the main encapsulation layer 110 covers the protected devices. In such case, the main body 110a covers a smooth surface of the protected devices, and the protrusion 110b covers the protrusive platform structure in order that the main encapsulation layer 110 adaptively sticks to the protected devices and covers the protected devices.

The auxiliary encapsulation layer 120 can be made of a material with a higher ladder coverage and a better density of film, such as inorganic materials including, but is not limited to, one or more of alumina, zirconia, and titanium oxide. In a specific embodiment, a material of the auxiliary encapsulation layer 120 is alumina, and the auxiliary encapsulation layer 120 can be made by an atomic layer deposition process. Of course, the auxiliary encapsulation layer 120 can also be prepared by film-forming processes, such as physical vapor deposition, pulsed laser deposition, and magnetron sputtering, according to film-forming characteristics of materials. The thickness of the auxiliary encapsulation layer 120 can be less than that of the main encapsulation layer 110. A ladder coverage of the main encapsulation layer 110 can be less than that of the auxiliary encapsulation layer 120.

It should be stated that the above ladder coverage can be realized as effects of an encapsulation layer covering a structure with a difference of height. For example, for the scene of covering the structure with a difference of height, the encapsulation layer covers a higher portion and a lower portion both, and is broken on the border between the higher portion and the lower portion (i.e., the main encapsulation layer 110 breaks). At this time, an incomplete coverage on the region is regarded as a lower ladder coverage of the encapsulation layer and materials thereof. If the above discontinuity or break does not exist, a ladder coverage of the encapsulation layer and materials thereof is regarded as being higher.

The auxiliary encapsulation layer 120 can cover one side of the main encapsulation layer 110, which is not limited to an underside shown in FIG. 1, or an upside of the main encapsulation layer 110 shown in FIG. 2, or two sides of the main encapsulation layer 110 shown in FIG. 3.

The encapsulation thin-film 100 combines the main encapsulation layer 110 with the auxiliary encapsulation layer 120. According to individual structural features, the main encapsulation layer 110 and the auxiliary encapsulation layer 120 cover the encapsulated surfaces using different features. That is, the main encapsulation layer 110 covers a whole coverage, and the auxiliary encapsulation layer 120 compensates the main encapsulation layer 110 for a region with a bad covering effect (which is referred as a predetermined region such as a region 130 where the protrusive structure is located) or strengthens the covering. When a break on the main encapsulation layer 110 occurs between the main body 110a and the protrusion 110b, the auxiliary encapsulation layer 120 makes the encapsulation thin-film 100 still have a complete layer of film of blocking water and oxygen molecules. When the break does not exist, the auxiliary encapsulation layer 120 can be used to strengthen a predetermined region of the main encapsulation layer 110 where the break may occur, providing a layer of film with a higher capability of blocking water and oxygen to be on a side of the protected devices. For example, as to the auxiliary encapsulation layer 120 made of alumina, its capability of blocking water and oxygen can be between 10⁻⁴ and 10⁻⁶ g/cm²/day and is very good.

It should be stated that the encapsulation thin-film 100 can be used in an encapsulation structure of an organic light-emitting diode display panel to protect components including organic light-emitting devices. That encapsulating the organic light-emitting devices is taken as an example below and is thoroughly described in conjunction with the accompanying drawings. It needs to be noted that in the full text of the present disclosure, same structural elements are marked by same numerals.

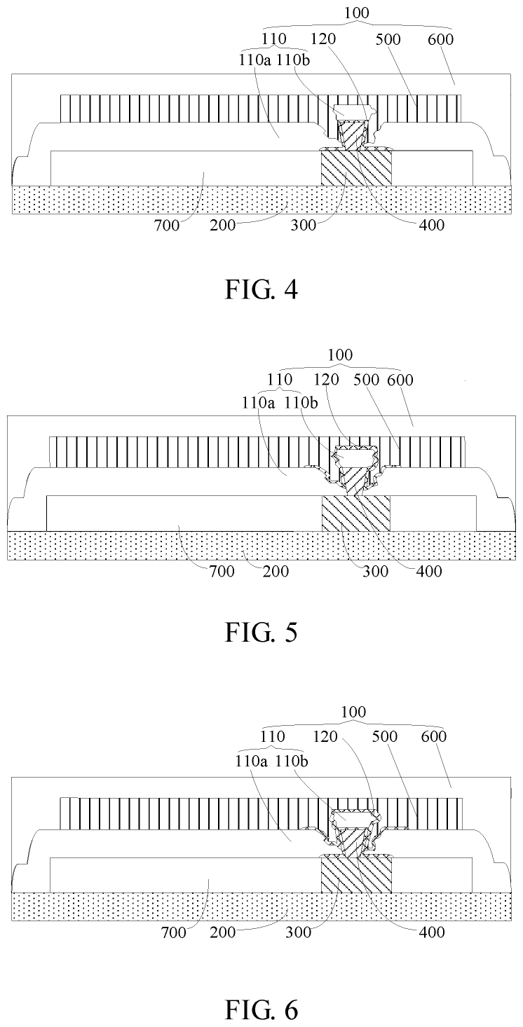

FIG. 4 is a schematic structural diagram of an organic light-emitting diode display panel according to a first embodiment of the present disclosure. Referring to FIG. 4, the organic light-emitting diode display panel can include an encapsulation thin-film 100, a substrate 200, a pixel define layer 300, a photo spacer 400, and organic light-emitting devices 700. The pixel define layer (PDL) 300 is located on the substrate 200 and is configured to define a pixel region of the organic light-emitting diode display panel. The organic light-emitting devices 700 are disposed on the substrate 200 and are located in the pixel region defined by the pixel define layer 300. The photo spacer (PS) 400 is located on the pixel define layer 300. The photo spacer 400 can be a structure of cylinder, round platform, cube, cuboid, and prism. The encapsulation thin-film 100 covers the photo spacer 400 and the pixel define layer 300.

The substrate 200 is used as an underlay substrate of the organic light-emitting diode display panel to carry each structural layer of the organic light-emitting diode display panel and electronic elements. In order to be adaptive to the bendability of the organic light-emitting diode display panel, the substrate 200 is a flexible plate with bendability. A main composition of the substrate 200 includes, but is not limited to, polyimide (PI). It can be selectable that the substrate 200 can cover a buffer layer. The buffer layer has a function of blocking water and oxygen. A main composition of the buffer layer includes, but is not limited to, silicon nitride, silicone compound, silicone nitrogen oxide, and so on. In addition, a variety of switching devices, such as thin film transistors, and traces are further disposed on the substrate 200 to make the organic light-emitting diode display panel display pictures.

The organic light-emitting devices 700 can include a control circuit layer (i.e., an array circuit layer), an anode, a hole transport layer (HTL), an organic light-emitting layer, an electronic transport layer (ETL), and a cathode, which can be referred in conventional technologies specifically.

The encapsulation thin-film 100 can include a first inorganic layer 110 (i.e., the main encapsulation layer 110), the auxiliary encapsulation layer 120, an organic layer 500, and a second inorganic layer 600. The first inorganic layer 110 covers the cathode of the organic light-emitting devices 700, the photo spacer 400, and the pixel define layer 300. Also, the first inorganic layer 110 further extends toward a side of the organic light-emitting devices 700 in order that the organic light-emitting devices 700 are encapsulated on the substrate 200. The organic layer 500 is located on the first inorganic layer 110 and can be made using an ink-jet printing (IJP) process. The second inorganic layer 600 covers the organic layer 500 and extends toward a side of the organic layer 500 to cover the first inorganic layer 110. The second inorganic layer 600 has a function of blocking water and oxygen and can be made of an inorganic material. It can be selectable that a material and a manufacturing method of the second inorganic layer 600 can be the same as those of the first inorganic layer 110, such as using a chemical vapor deposition (CVD) process.

In the manufacturing process of the organic light-emitting devices 700, a fine metal mask (FMM) is used to evaporate an organic light-emitting layer, etc. In order to prevent the damage of the pixel define layer 300 caused by that the FMM is in contact with the substrate 200 directly, the photo spacer 400 shown in FIG. 4 is used as a support between the FMM and the pixel define layer 300. The height of the photo spacer 400 is generally between 1 μm and 3 μm. Because of a lower ladder coverage of the first inorganic layer 110 caused by characteristics of inorganic materials, such as silicon nitride, silica, silicone nitrogen oxide, and because a thickness of the first inorganic layer 110 is generally between 0.5 μm and 1.5 μm, there is the possibility that the first inorganic layer 110 breaks while being formed on the photo spacer 400, causing the first inorganic layer 110 to break into two parts when the first inorganic layer 110 covers the photo spacer 400 and the pixel define layer 300. That is, the main body 110a and the protrusion 110b are shown in FIG. 4, and a top surface of the protrusion 110b is not flush with a top surface of the main body 110a.

The auxiliary encapsulation layer 120 is disposed on the underside of the first inorganic layer 110 and covers an orthogonal projection of the photo spacer 400 on the pixel define layer 300. That is, the auxiliary encapsulation layer 120 covers a top surface and a side surface of the photo spacer 400. It can be selectable that the auxiliary encapsulation layer 120 can cover the whole of an orthogonal projection of the pixel define layer 300 on the substrate 200. In other words, an orthogonal projection of the pixel define layer 300 on the first inorganic layer 110 lies within a coverage of the auxiliary encapsulation layer 120. Accordingly, the auxiliary encapsulation layer 120 overlaps with a part of the underside of the main body 110a of the first inorganic layer 110 so that a larger coverage is realized.

A thickness of the auxiliary encapsulation layer 120 can be between 20 nm and 100 nm, and the auxiliary encapsulation layer 120 can be made of a material with a higher ladder coverage and a better density of film, such as inorganic materials including, but is not limited to, one or more of alumina, zirconia, and titanium oxide. In a specific embodiment, the auxiliary encapsulation layer 120 can be made by an atomic layer deposition process. Of course, the auxiliary encapsulation layer 120 can also be prepared by film-forming processes, such as physical vapor deposition, pulsed laser deposition, and magnetron sputtering, according to the property of materials used in the specific embodiment. The thickness of the auxiliary encapsulation layer 120 can be less than that of the main encapsulation layer 110. A ladder coverage of the first inorganic layer 110 can be less than that of the auxiliary encapsulation layer 120.

The organic light-emitting diode display panel combines the first inorganic layer 110 with the auxiliary encapsulation layer 120. According to individual structural features, the first inorganic layer 110 and the auxiliary encapsulation layer 120 cover the surfaces of the photo spacer 400 and the pixel define layer 300 using different features. That is, the first inorganic layer 110 covers a whole coverage, and the auxiliary encapsulation layer 120 compensates the first inorganic layer 110 for a region with a bad covering effect (such as an orthogonal projection of the photo spacer 400 on the pixel define layer 300) or strengthens the covering. When a break on the first inorganic layer 110 occurs between the main body 110a and the protrusion 110b, the auxiliary encapsulation layer 120 makes the encapsulation thin-film 100 still have a layer of film of blocking water and oxygen molecules. When the break does not exist, the auxiliary encapsulation layer 120 can be used to strengthen a region of the first inorganic layer 110 where the break occurs, providing a layer of film with a higher capability of blocking water and oxygen to be on a side of the organic light-emitting devices 700 protected.

Based on the features of the auxiliary encapsulation layer 120, the auxiliary encapsulation layer 120 can further cover the upside of the first inorganic layer 110. As shown in FIG. 5, the auxiliary encapsulation layer 120 covers the photo spacer 400 directly. Specifically, the auxiliary encapsulation layer 120 covers a top surface and a side surface of the photo spacer 400, and an upper surface of the pixel define layer 300 adjacent to the photo spacer 400. At this time, the auxiliary encapsulation layer 120 also compensates the first inorganic layer 110 for a region with a bad covering effect (such as an orthogonal projection of the photo spacer 400 on the pixel define layer 300) or strengthens the covering. A channel for water and oxygen located at the breakage in the first inorganic layer 110 is blocked by the auxiliary encapsulation layer 120, ensuring the ability of blocking water and oxygen from entering the organic light-emitting devices 700. It is beneficial to guarantee normal use of the organic light-emitting devices 700.

As shown in FIG. 6, the auxiliary encapsulation layer 120 can also cover two sides of the first inorganic layer 110. That is, the auxiliary encapsulation layer 120 includes two parts, which partly covers the photo spacer 400 directly (specifically, the auxiliary encapsulation layer 120 covers a top surface and a side surface of the photo spacer 400, and an upper surface of the pixel define layer 300 adjacent to the photo spacer 400); and partly covers the upside of the first inorganic layer 110 (such arrangement can be the same as that of the auxiliary encapsulation layer 120 shown in FIG. 4).

The auxiliary encapsulation layer 120 compensates the first inorganic layer 110 and strengthens the covering. A layer of film of blocking water and oxygen molecules is constructed more completely, making full use of the features of the auxiliary encapsulation layer 120 such as a relatively higher ladder coverage and a high density and also making use of the first inorganic layer 110 as a main body of encapsulation. An effective encapsulating protection is provided for the organic light-emitting devices 700 on a side of a covering surface.

Please refer to FIGS. 4-6, an encapsulation structure for the organic light-emitting devices 700 further includes an organic layer 500 and a second inorganic layer 600. In a specific embodiment, at least one of the first inorganic layer 110, the organic layer 500, the second inorganic layer 600, and the auxiliary encapsulation layer 120 can be doped with a water-absorbing material. The water-absorbing material can be used to absorb water molecules in the first inorganic layer 110, the organic layer 500, the second inorganic layer 600, and the auxiliary encapsulation layer 120. The introduction of the water-absorbing material provides one more guarantee of blocking water molecules and increases difficulty for water molecules in reaching the organic light-emitting devices 700, further improving the capability of blocking water molecules.

It can be selectable that the water-absorbing material can be nano-scale calcium oxide, i.e., nano-scale calcium oxide particles. A doping concentration of the water-absorbing material can gradually increase along a direction from the second inorganic layer 600 toward the photo spacer 400 and the pixel define layer 300. That is, a region which may have a break closer to the first inorganic layer 110 has a higher doping concentration of the water-absorbing material.

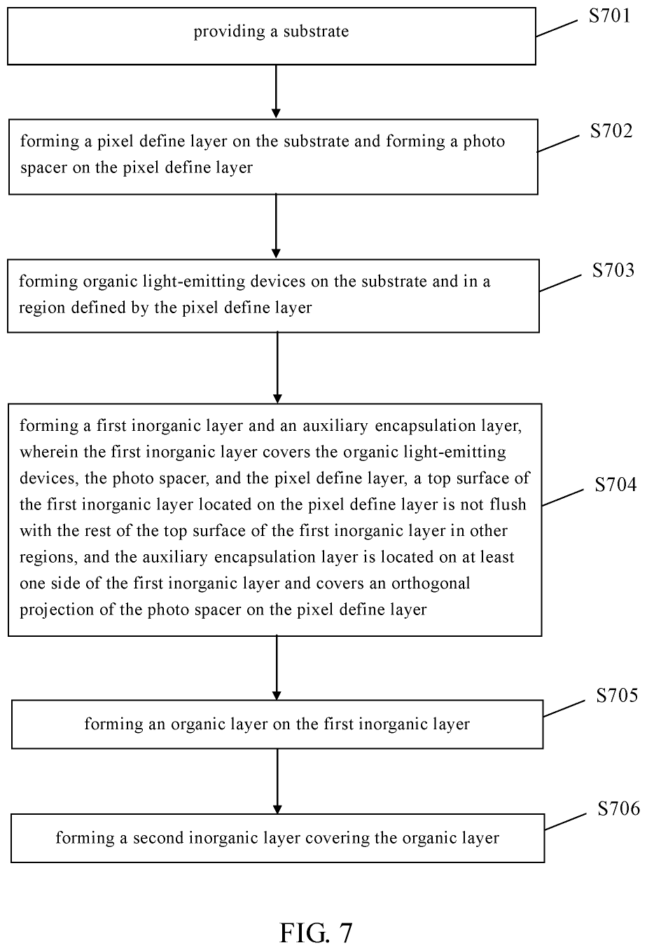

FIG. 7 is a schematic flowchart illustrating a method of manufacturing an organic light-emitting diode display panel according to an embodiment of the present disclosure. Please refer to FIG. 7, the method of manufacturing the organic light-emitting diode display panel includes:

S701: providing a substrate;

S702: forming a pixel define layer on the substrate and forming a photo spacer on the pixel define layer;

S703: forming organic light-emitting devices on the substrate and in a region defined by the pixel define layer;

S704: forming a first inorganic layer and an auxiliary encapsulation layer, wherein the first inorganic layer covers the organic light-emitting devices, the photo spacer, and the pixel define layer, a top surface of the first inorganic layer located on the pixel define layer is not flush with the rest of the top surface of the first inorganic layer in other regions, and the auxiliary encapsulation layer is located on at least one side of the first inorganic layer and covers an orthogonal projection of the photo spacer on the pixel define layer;

S705: forming an organic layer on the first inorganic layer; and

S706: forming a second inorganic layer covering the organic layer.

The manufacturing method ensures the ability of blocking water and oxygen from entering organic light-emitting devices through adding an auxiliary encapsulation layer on at least one side of an inorganic layer, and through the auxiliary encapsulation layer covering an orthogonal projection of a photo spacer on a pixel define layer. Even if the inorganic layer breaks while covering the photo spacer, a channel for water and oxygen located at the breakage is blocked by the auxiliary encapsulation layer.

The manufacturing method can be used to manufacture the foregoing organic light-emitting diode display panel. Each structural element prepared by the manufacturing method can be referred in the above description and is not repeated here.

While the present disclosure has been illustrated and described with respect to one or more implementations, it will be apparent to those skilled in the art that equivalent variations and modifications will be thought based on reading and understanding of the present specification and drawings. The disclosure includes all such modifications and variations, and is limited only by the scope of the appended claims. In particular, with respect to the various functions performed by the above-described components, the terminology used to describe such a component is intended to correspond to any component (unless otherwise indicated) that performs a specified function of the component (e.g., it is functionally equivalent), even if they are not structurally equivalent to the public structure of the functions in the exemplary implementation of the present specification as shown herein. In addition, although the particular features of the specification have been disclosed with respect to only one of several implementations, such features may be combined with one or more other features of other implementations that may be desirable and advantageous for a given or specific application. Also, with regard to the terms “including”, “having”, “containing”, or their variations used in the specific embodiments or claims, they are intended to “limit” in a way similar to the term “comprising”. Further, it should be understood that “plurality” means at least two. As to the steps mentioned in the description, their numeral suffixes are merely for clearly describing and realizing embodiments. The numeral suffixes are not fully representative of order of implementing steps but should be considered in relation to priority setting of logical relation instead.

The above descriptions are only the embodiments of the present disclosure, but are not intended to limit the scope of the present disclosure. Any transform of equivalent structures or process which is made according to the specification and the attached drawings of the present disclosure, such as a mutual combination of technical features in each embodiment, or any direct or indirect applications of the present disclosure in other related technical fields shall all be covered within the protective scope of claims of the present disclosure.

What is claimed is:

1. An organic light-emitting diode display panel, comprising:
a pixel define layer;
a photo spacer located on the pixel define layer;
a first inorganic layer configured to encapsulate organic light-emitting devices; and
an auxiliary encapsulation layer located on at least one side of the first inorganic layer and covering an orthogonal projection of the photo spacer on the pixel define layer;
wherein the first inorganic layer covers the photo spacer and the pixel define layer, and a top surface of the first inorganic layer covering the pixel define layer is not flush with the rest of the top surface of the first inorganic layer covering other regions.

2. The organic light-emitting diode display panel of claim 1, wherein an orthogonal projection of the pixel define layer on the first inorganic layer lies within a coverage of the auxiliary encapsulation layer.

3. The organic light-emitting diode display panel of claim 1, wherein a material composition of the auxiliary encapsulation layer comprises one or more of alumina, zirconia, and titanium oxide.

4. The organic light-emitting diode display panel of claim 1, further comprising an organic layer and a second inorganic layer, which are configured to encapsulate the organic light-emitting devices and overlap on the first inorganic layer sequentially, wherein at least one of the first inorganic layer, the organic layer, the second inorganic layer, and the auxiliary encapsulation layer is doped with a water-absorbing material.

5. The organic light-emitting diode display panel of claim 4, wherein concentration of the water-absorbing material gradually increases along a direction from the second inorganic layer toward the photo spacer and the pixel define layer.

6. An encapsulation thin-film, comprising a main encapsulation layer and an auxiliary encapsulation layer, wherein a top surface of the main encapsulation layer in a predetermined region is not flush with the rest of the top surface in other regions, and the auxiliary encapsulation layer is located on at least one side of the main encapsulation layer and covers the predetermined region.

7. The encapsulation thin-film of claim 6, wherein a material composition of the auxiliary encapsulation layer comprises one or more of alumina, zirconia, and titanium oxide.

8. The encapsulation thin-film of claim 6, wherein a main material composition of the main encapsulation layer is an inorganic material.

9. The encapsulation thin-film of claim 6, wherein at least one of the main encapsulation layer and the auxiliary encapsulation layer is doped with a water-absorbing material.

10. The encapsulation thin-film of claim 9, wherein concentration of the water-absorbing material gradually increases along a direction toward the predetermined region.

11. A method of manufacturing an organic light-emitting diode display panel, comprising:
providing a substrate;
forming a pixel define layer on the substrate and forming a photo spacer on the pixel define layer;
forming organic light-emitting devices on the substrate and in a region defined by the pixel define layer;
forming a first inorganic layer and an auxiliary encapsulation layer, wherein the first inorganic layer covers the organic light-emitting devices, the photo spacer, and the pixel define layer, a top surface of the first inorganic layer located on the pixel define layer is not flush with the rest of the top surface of the first inorganic layer in other regions, and the auxiliary encapsulation layer is located on at least one side of the first inorganic layer and covers an orthogonal projection of the photo spacer on the pixel define layer;
forming an organic layer on the first inorganic layer; and
forming a second inorganic layer covering the organic layer.

12. The method of claim 11, wherein an orthogonal projection of the pixel define layer on the first inorganic layer lies within a coverage of the auxiliary encapsulation layer.

13. The method of claim 11, wherein the auxiliary encapsulation layer is formed from a material comprising one or more of alumina, zirconia, and titanium oxide.

14. The method of claim 11, wherein the forming of the first inorganic layer and the auxiliary encapsulation layer comprises one of steps of:
forming the first inorganic layer doped with a water-absorbing material;
forming the auxiliary encapsulation layer doped with the water-absorbing material; and
forming the first inorganic layer and the auxiliary encapsulation layer which are doped with the water-absorbing material.

15. The method of claim 14, wherein concentration of the water-absorbing material gradually increases along a direction from the second inorganic layer toward the photo spacer.

16. The method of claim 11, wherein the step of forming the organic layer on the first inorganic layer comprises forming the organic layer doped with a water-absorbing material on the first inorganic layer.

17. The method of claim 16, wherein concentration of the water-absorbing material gradually increases along a direction from the second inorganic layer toward the photo spacer.

18. The method of claim 11, wherein the forming of the second inorganic layer covering the organic layer comprises forming the second inorganic layer covering the organic layer and doped with a water-absorbing material.

19. The method of claim 18, wherein concentration of the water-absorbing material gradually increases along a direction from the second inorganic layer toward the photo spacer.
